(19) United States
(12) Patent Application Publication
(10) Pub. No.: US 2025/0377321 A1
(43) Pub. Date: Dec. 11, 2025

(54) Method and apparatus for measuring soil moisture and composition

(71) Applicant: resonAg Pty Ltd, Pickering Brook (AU)

(72) Inventors: Timothy Andrew John HOPPER, Pickering Brook (AU); Rebecca Anne HOPPER, Pickering Brook (AU)

(21) Appl. No.: 19/227,783

(22) Filed: Jun. 4, 2025

(30) Foreign Application Priority Data
Jun. 5, 2024 (AU) 2024901690

(51) Int. Cl. G01N 24/08; A01B 76/00

(52) U.S. Cl. CPC G01N 24/081; A01B 76/00

(57) ABSTRACT

An apparatus for measuring soil moisture and composition includes a ground engaging element adapted to break the surface of the soil, the ground engaging element having at least one NMR and/or NQR probe such that in use, the at least one NMR and/or NQR probe is under the surface of the soil. A method of measuring soil moisture and composition includes conducting NMR and/or NQR analyses of soil below the surface at a substantially constant depth.

### TECHNICAL FIELD

The present invention relates to methods and apparatus for measuring soil moisture and composition.

### BACKGROUND ART

In many instances and in particular in agriculture, there is a desire to know the composition of the ground. Elemental analysis for soil is normally acquired on samples taken from the field followed by offsite analysis in a laboratory. The method is time consuming and depending on the number of samples taken, not reflective of localised variations.

Current methods to determine nutrient requirements of an area comprise taking soil samples in a grid pattern. Accurately determining soil composition for farms can require hundreds or thousands of soil samples. The cost is prohibitive and time consuming.

More generally, the inputs to run a broadacre farm are becoming unsustainable, both financially and from a soil health perspective. With a greater understanding of the role that a healthy soil plays, farming is very rapidly moving towards a fully autonomous system where the soil is measured and inputs to the system are administered only as required.

Laser-induced breakdown spectroscopy (LIBS) is a type of atomic emission spectroscopy which uses a highly energetic laser pulse as the excitation source. The laser is focussed to form a plasma which atomises and excites samples. The formation of the plasma only begins when the focused laser achieves a certain threshold for optical breakdown, which generally depends on the environment and the target sample.

LIBS has been used to determined elemental analysis in agriculture. However, LIBS only utilises a very small sample size (1-2 microns) and is very susceptible to contamination. Such a small volume mean that it is not truly representative of the region.

Infrared technology has also been used to analyse soils. However, infrared technology does not measure elements. An infrared spectrometer analyses a compound by passing infrared radiation, over a range of different frequencies, through a sample and measuring the absorptions made by the bonds in the compound. Infrared measures functional groups and requires a model to convert is back to a carbon content. The model is complex and changes with each soil type.

The reliable measurement of soil moisture and composition in real time and in situ, remains a challenge.

The preceding discussion of the background to the invention is intended to facilitate an understanding of the present invention. However, it should be appreciated that the discussion is not an acknowledgement or admission that any of the material referred to was part of the common general knowledge as at the priority date of the application.

Throughout the specification, unless the context requires otherwise, the word “comprise” or variations such as “comprises” or “comprising”, will be understood to imply the inclusion of a stated integer or group of integers but not the exclusion of any other integer or group of integers.

Those skilled in the art will appreciate that the invention described herein is susceptible to variations and modifications other than those specifically described. It is to be understood that the invention includes all such variations and modifications. The invention also includes all of the steps, features, compositions and compounds referenced to or indicated in the specification, individually or collectively and any and all combinations or any two or more of the steps or features.

The present invention is not to be limited in scope by the specific embodiments described herein, which are intended for the purpose of exemplification only. Functionally equivalent products, compositions and methods are clearly within the scope of the invention as described herein. The entire disclosures of all publications (including patents, patent applications, journal articles, laboratory manuals, books, or other documents) cited herein are hereby incorporated by reference.

### SUMMARY OF INVENTION

In accordance with the present invention, there is provided an apparatus for measuring soil moisture and composition, the apparatus comprising a ground engaging element adapted to break the surface of the soil, the ground engaging element comprising at least one NMR and/or NQR probe such that in use, the at least one NMR and/or NQR probe is under the surface of the soil.

Preferably, the NMR and/or NQR probes are under the surface of the soil at substantially constant depths.

Preferably, the soil is an area of land, the moisture content and composition of which are desired.

In one form of the invention, the area of land is agricultural land. In one form of the invention, the area of land is an anthropogenic land such as landfill or contaminated sites.

In the context of the present invention, the term soil composition comprises the chemical composition of the soil. Advantageously, the moisture and chemical composition of the soil can be used to provide a soil profile. In one form of the invention, the soil profile is a three dimensional soil profile. It will be appreciated that NMR analysis is restricted to those atomic nuclei that possess a magnetic moment and angular momentum such as hydrogen, carbon, boron, fluorine, nitrogen, oxygen and phosphorous. It will be appreciated that ¹H NMR data can be used to provide an indication of the moisture levels in the soil. It will be appreciated that ¹³C NMR data can be used to provide an indication of the Total Organic Carbon (TOC) levels in the soil. Other elemental analyses may be used, for example, to provide an indication of soil health or nutrient levels in the soil.

Advantageously, the elemental analysis is very rapid, and results are available in real time.

In one form of the invention, the apparatus is provided with means to traverse the area of land. In an alternate form of the invention, the apparatus is attached to means to traverse the area of land. The apparatus may traverse the area of land by being provided on a vehicle or being towed by a vehicle. In one form of the invention, the apparatus is attached to an agricultural tine. In one form of the invention, the apparatus is attached to an agricultural seeder. In one form of the invention, there are provided a plurality of tines attached to a seeder.

Where there are provided a plurality of tines attached to a seeder, each tine may be provided with an apparatus of the present invention. Where there are provided a plurality of tines attached to a seeder, an apparatus of the present invention may alternatively be attached to the seeder in between each tine. Alternatively still, the apparatus may be attached to the tine adjacent a knife.

The apparatus may be attached to the seeder.

The seeder may be provided with one apparatus. The seeder may be provided with more than one apparatus.

The seeder may be provided with more than one tine wherein each tine comprises an apparatus for measuring soil moisture and composition.

The seeder may be provided with more than one tine and an equal number of apparatus for measuring soil moisture and composition. The seeder may be provided with more than one tine and a lesser number of apparatus for measuring soil moisture and composition. The seeder may be provided with more than one tine and one apparatus for measuring soil moisture and composition.

Preferably, the NMR and/or NQR probes are under the surface of the soil at substantially constant depths while the apparatus is traversing the area of land.

The apparatus is adapted to conduct constant NMR and/or NQR analyses while traversing the area of land. The apparatus is adapted to conduct constant NMR and/or NQR analyses at substantially constant depths while traversing the area of land.

Preferably, there are provided a plurality of ground engaging elements.

There may be provided biasing means to maintain the ground engaging element at substantially constant depth during operation.

The at least one NMR and/or NQR probes are provided on the ground engaging element such that they are maintained at substantially constant depth in the soil when in use.

In the context of the present specification, the term depth shall be understood to be the distance below the surface of the soil.

The NMR and/or NQR probe may comprise a permanent magnet and an induction coil. The apparatus may further comprise an Application-Specific-Integrated-Circuit (ASIC).

Preferably, the apparatus comprises means to acquire NMR and/or NQR data. Preferably, the apparatus, comprises a processor adapted to analyse the NMR and/or NQR data.

In one form of the invention, the ground engaging element is provided in the form of a furrow former, a coulter or a knife.

The furrow former may be provided in the form of a single disc or double discs or a knife point plough.

In one form of the invention, the furrow former is provided as a pair of rotatable discs adapted to engage the soil and form a furrow. A non-rotatable element may be provided on one of the rotatable discs.

In one form of the invention, the non-rotatable element is provided in the form of a non-rotatable wheel. The non-rotatable wheel may be attached to the rotatable disc by a series of bearings such that the non-rotatable wheel remains in a fixed position even when the rotatable disc is rotating. In this configuration, the non-rotatable wheel remains in a fixed position when the apparatus traverses the area of land.

The plurality of NMR and/or NQR probes may be provided on the non-rotatable wheel. In this configuration, the at least one NMR and/or NQR probes remain at a substantially constant soil depth when the apparatus traverses the area of land.

In the context of the present invention, the term non-rotatable shall be understood to refer to a wheel that does not appear to rotate while the rotatable disc rotates. In practice, the non-rotatable when may rotate counter to the movement of the rotatable disc thus giving the appearance of being stationary.

Where the ground engaging element is provided in the form of a knife, the at least one NMR and/or NQR probes may be provided at different locations along the knife.

Preferably, the knife is non-magnetic, for example ceramic or tungsten carbide. A wear plate may be provided on the outside of the knife to protect the NMR and/or NQR components.

Where the knife is magnetic, the RF coil should be remote from the magnetic material. A distance of at least 6 cm is preferred.

Knives can be subject to high impact when engaging rocks and the like. For protection, the ground engaging element comprising the NMR and NQR probes may be located behind the knife.

In one form of the invention, the apparatus further comprises a furrow closer.

In one form of the invention, the apparatus further comprises a seed delivery system.

In one form of the invention, the apparatus further comprises a fertiliser delivery system. Where provided, the fertiliser delivery system may be adapted to deliver one or both of liquid and granular fertiliser.

In one form of the invention, the apparatus further comprises a water delivery system.

In one form of the invention, the apparatus further comprises at least one of a seed delivery system, a fertiliser delivery system and a water delivery system.

Preferably, the seed delivery system is adapted to deliver seed to the soil in response to the elemental analysis in real time. Preferably, the seed delivery system is adapted to vary the seed delivery depth in response to the elemental analysis in real time. This is particularly the case where the elemental analysis provides soil and moisture content information.

Preferably, the fertiliser delivery system is adapted to deliver fertiliser to the soil in response to the elemental analysis in real time. Preferably, the fertiliser delivery system is adapted to vary the fertiliser quantity in response to the elemental analysis in real time.

Preferably, the water delivery system is adapted to deliver water to the soil in response to the elemental analysis in real time. Preferably, the water delivery system is adapted to vary the water quantity in response to the elemental analysis in real time.

In accordance with the present invention, there is provided a method of measuring soil composition, wherein the method comprises conducting NMR and/or NQR analyses of soil below the surface at a substantially constant depth.

Preferably, the method comprises conducting NMR and/or NQR analyses of soil at multiple soil depths. Preferably, the method comprises conducting NMR and/or NQR analyses of soil at multiple soil depths concurrently.

Preferably, the method comprises conducting NMR and/or NQR analyses of soil at multiple geospatial locations.

Preferably, the method comprises the additional step of creating an elemental profile of the soil.

Preferably, the step of conducting NMR and/or NQR analyses of soil comprises:
engaging the soil with a ground engaging element comprising at least one NMR and/or NQR probes; and
maintaining each NMR and/or NQR probe at a substantially constant depth;
while conducting NMR and/or NQR analyses.

Preferably, the step of conducting NMR and/or NQR analyses of soil at multiple geospatial locations comprises geospatially moving the ground engaging element comprising at least one NMR and/or NQR probes across the soil while conducting NMR and/or NQR analyses.

In one form of the invention, the geospatial location of an NMR and/or NQR probe at the point of analysis is determined by GPS. Alternatively, the location can be determined by a mobile radio network.

The method of the present invention provides a two or three dimensional moisture or elemental profile of the ground. On the basis of the profile, for example, pollutant concentration in anthropogenic influenced grounds can be detected. Alternatively, planting, fertilising and water programmes for agricultural ground can be prepared. Advantageously, fertilisation and watering programs may be location dependent. Advantageously, seeds may be planted at different depths on the basis of the elemental profile.

Advantageously, the method of the present invention enables the dynamic characterisation of soil.

Preferably, the ground engaging element forms a furrow.

The present invention may be utilised in an agricultural planting program.

In one form of the invention, there is provided the additional step of:
planting seeds in the furrow.

The step of planting seeds in the furrow may be conducted substantially simultaneously with the step of conducting NMR and/or NQR analyses of the soil.

In one form of the invention, the step of planting seeds in the furrow comprises planting seeds in the furrow at varying depths based on the NMR and/or NQR analyses of the soil.

In one form of the invention, there is provided the additional step of watering the soil.

The step of watering the soil may be conducted substantially simultaneously with the step of conducting NMR and/or NQR analyses of the soil.

In one form of the invention, the step of watering the soil comprises watering the soil based on the NMR and/or NQR analyses of the soil. That is, the volume of water may be adjusted based on the results of the NMR and/or NQR analyses. Said adjustments may be conducted in real time.

In one form of the invention, there is provided the additional step of fertilising the soil.

The step of fertilising the soil may be conducted substantially simultaneously with the step of conducting NMR and/or NQR analyses of the soil.

In one form of the invention, the step of fertilising the soil comprises fertilising the soil based on the NMR and/or NQR analyses of the soil. That is, the amount of fertiliser may be adjusted based on the results of the NMR and/or NQR analyses. Said adjustments may be conducted in real time.

Advantageously, the present invention rapidly and continuously provides elemental analysis of the soil. This information is continuously reported to fertiliser, water and seeding applicators that are responsive to the elemental analysis.

For example, the moisture content of the soil can influence seed planting depths. This information may be acted on in real time and seeds planting depths controlled prior to the furrow closing.

Advantageously, the present invention rapidly determines moisture levels and consequently, analysis can be conducted in real time allowing seeds to be planted at different depths prior to the furrow closing.

Alternatively, information on elemental concentration of, for example, nitrogen, phosphorous and potassium may impact fertiliser dosing in a furrow in real time.

The method of the present invention may be fully autonomous where the soil is continuously measured, and inputs are administered as required.

### BRIEF DESCRIPTION OF THE DRAWINGS

Further features of the present invention are more fully described in the following description of several non-limiting embodiments thereof. This description is included solely for the purposes of exemplifying the present invention. It should not be understood as a restriction on the broad summary, disclosure or description of the invention as set out above. The description will be made with reference to the accompanying drawings in which:

FIG. 1 is an isometric view of a schematic of a portion of an agricultural seeder;

FIG. 2 is an isometric view of a knife;

FIG. 3 is a cross-sectional side view of a knife;

FIG. 4 is a side view of a knife;

FIG. 5 is a side view of a knife;

FIG. 6 is a side view of a furrow former;

FIG. 7 is a side view of a furrow former;

FIG. 8 is a side view of a furrow former;

FIG. 9 is a cross-sectional side view of a furrow former;

FIG. 10 is an isometric view of a furrow former;

FIG. 11 is the internal components of an NMR sensor;

FIG. 12 is a schematic of a series of magnets;

FIG. 13 is a schematic of a series of magnets showing magnetic field potential lines;

FIG. 14 is a plot of the static magnetic field; and

FIG. 15 is a plot of the B₀ field perpendicular to the magnet face.

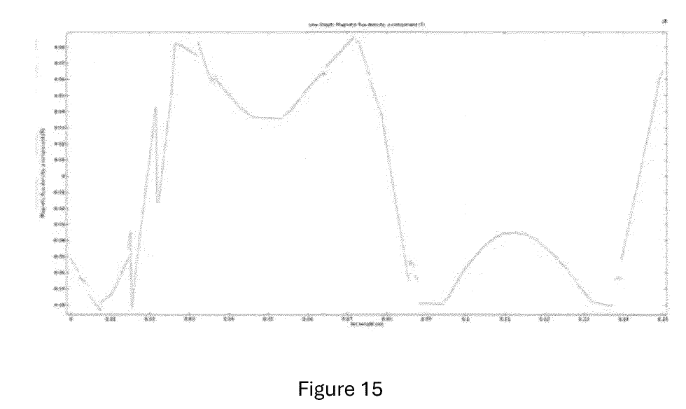

### DESCRIPTION OF EMBODIMENTS

Agricultural seeders are machines adapted to meter predetermined quantities of seeds or fertiliser or the like. Seed and fertiliser placement is programmed with little, or no consideration given to the local conditions.

Tines of the prior art are known to comprise hydraulic, pneumatic or mechanical biasing means such as a ram and a furrow forming means along with combinations of water, seed and fertiliser delivery systems. A gauge wheel or skid may be provided leading the furrow former. A press wheel may be provided following the furrow former to close the furrow. A plurality of tines will often be provided on an agricultural seeder.

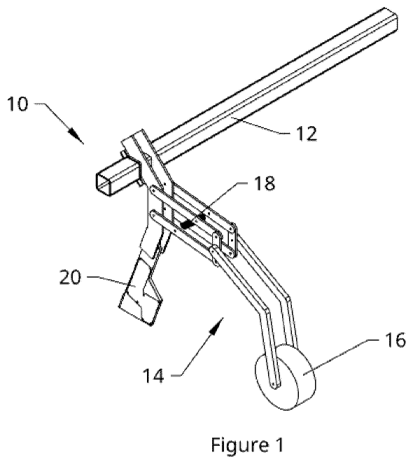

In FIG. 1 there is provided a schematic of a portion of an agricultural seeder 10 depicting a seeder bar 12 and a simplified tine 14. The simplified tine comprises a press wheel 16, mechanical biasing means 18 and a knife 20. The apparatus for determining soil moisture and composition is provided within the knife 20. In one embodiment, the simplified tine 14 is mounted on the seeder bar 12 in between the standard tines (not shown). There may be provided one or more simplified tines 14 on the seeder bar 12.

The biasing means 18 is provided in the form of a spring loaded parallelogram, adapted to maintain the knife 20 in the ground at substantially constant depth during operation.

In use, the seeder 10 is towed across a field with a row cleaner at the front. The row cleaner is intended to remove debris, and the furrow opener forms a furrow in the soil. The furrow closer closes the furrow. A downforce generator is provided to provide constant downward force. There may also be provided substance delivery systems to deliver other substances such as fertiliser. There is generally provided a number of these furrow units operating in tandem to provide greater coverage.

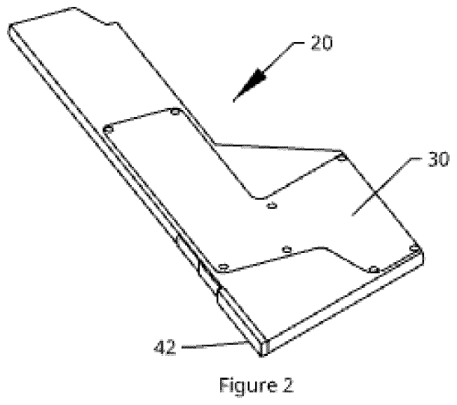

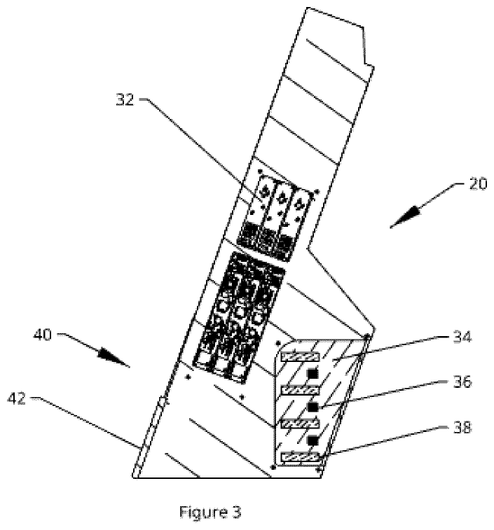

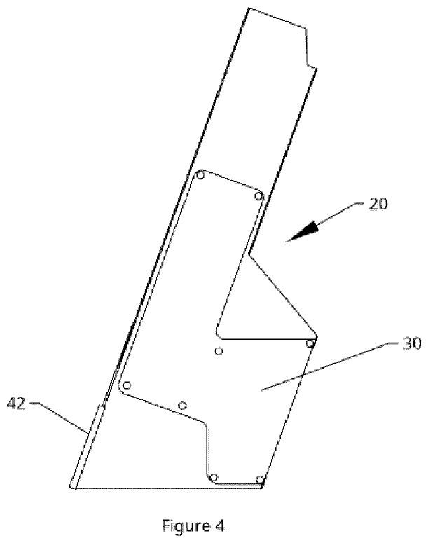

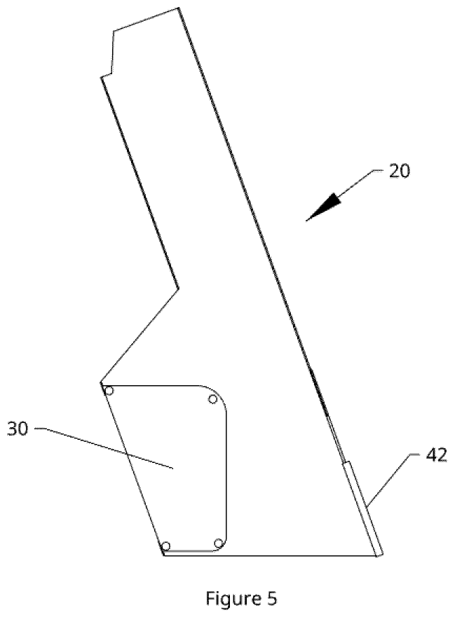

In FIGS. 2 to 5, there are provided views of a knife 20 comprising an embodiment of the apparatus of the present invention. The knife 20 comprises a wear plate 30 to protect the components of the NMR. Under the wear plate 30 is provided the electronics 32 to operate the NMR, the NMR chassis 34, the coil 36 and the permanent magnet 38. The leading edge 40 of the tine 20 may further comprise a protective tungsten carbide tip 42.

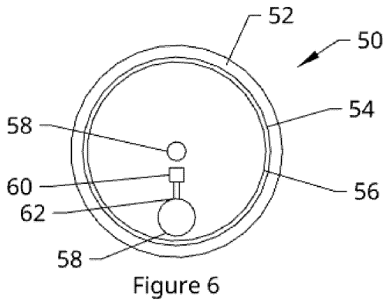

In FIG. 6 there is provided a schematic of a furrow former 50 in accordance with an embodiment of the invention. The furrow former 50 comprises an outer disc 52 that rotates in the ground as the vehicle moves across the field. A bearing section 54 is provided to allow counter rotation. An inner disc 56 has NMR sensors 58 mounted. Only one sensor is shown in FIG. 6, although it will be appreciated that there may be more. The disc centre 58 comprises a stepper motor to turn the inner disc 56 responsive to movement of the outer disc 52. The furrow former 50 may further comprise an NMR/NQR spectrometer PCB/chip 60, a cable 62 to connect the PCB/chip 60 to the NMR/NQR sensor 58. The NMR/NQR sensor 58 may comprise a magnet array, RF coil and tuning capacitors (not shown) as is known in the art.

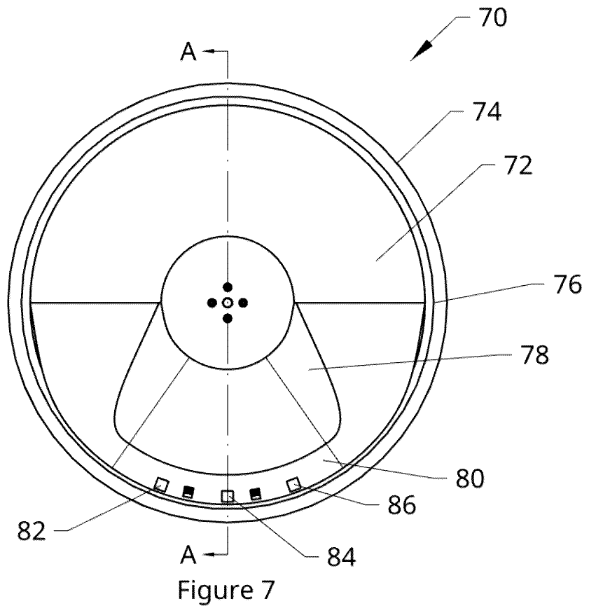

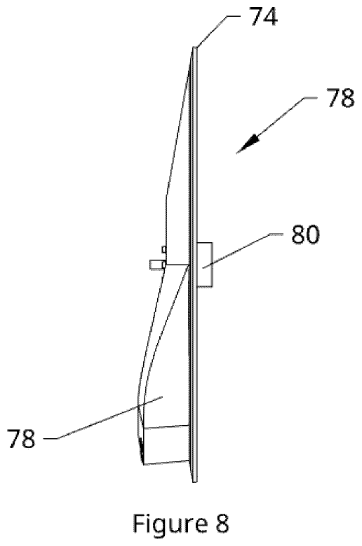

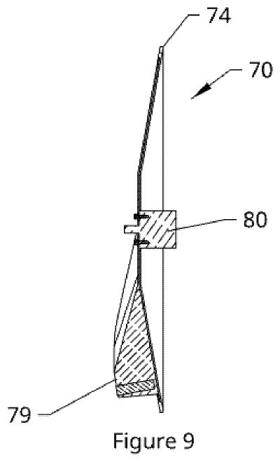

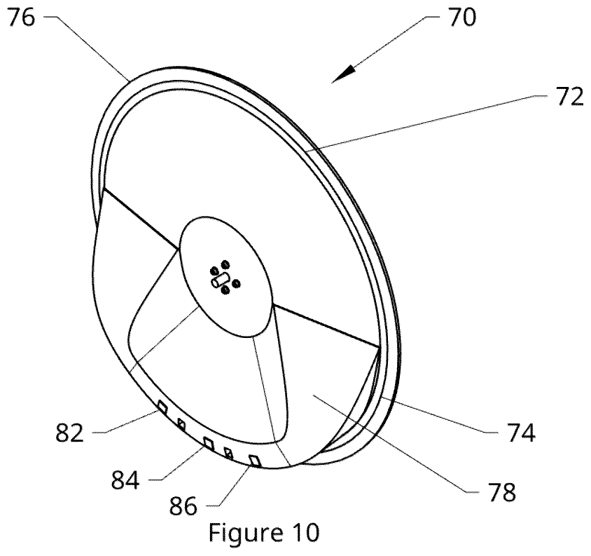

In FIGS. 7 to 10 the provided schematics of a furrow former 70 in accordance with an alternate embodiment of the invention. The furrow former 70 comprises a tine body 72 and a tine blade 74 as is known in the art. A bearing 76 is provided to allow for counter-rotation of a non-rotating wheel portion 78. The centre of the circular tine body 72 comprises a stepper motor 80 to turn the non-rotating wheel portion 78 responsive to movement of the tine body 72. The non-rotating wheel portion 78 is semicircular and is thicker at the circumference than the interior, tapering from the interior to the exterior to retain the NMR sensor pack 80. The sensor pack 80 depicted in FIG. 7 depicts three NMR sensors 82, 84, 86.

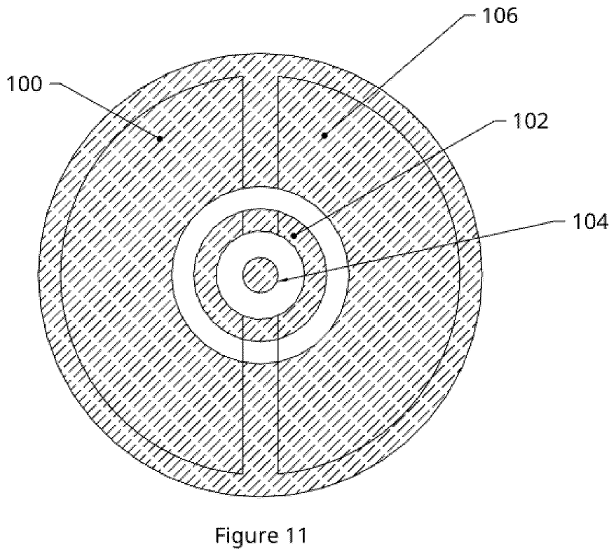

FIG. 11 depicts the internal of an NMR sensor in accordance with an embodiment of the invention comprising a three barrel magnet array comprising an outer magnet 100, a middle magnet 102 and an inner magnet 104. A figure eight RF coil 106 is provided to make the RF (B₁) field perpendicular to the statis (B₀) magnetic field.

Nuclear Magnetic Resonance (NMR) involves the generation of a static magnetic field within a sample, emission of Radio Frequency (RF) pulses into the sample and detection of RF NMR responses from the sample.

NMR signals arise from the magnetic properties of atomic nuclei (in particular the magnetic moment and angular momentum of the nuclear spin). Not all atomic nuclei possess a magnetic moment and angular momentum, and hence not all nuclei yield an observable NMR signal. Atoms that do possess a nuclear spin are also known to differ from one another due to differences in nuclear structure.

NMR spectrometers generally comprise the following components:
a magnetic coil to generate an electromagnetic field on current flow;
a permanent magnet to provide a homogenous magnetic field;
a radiofrequency transmitter to produce radio waves pulses;
a radiofrequency detector to measure the NMR signal from the sample;
a digitiser and analogue to digital converter to record the NMR signals received by the RF detector; and
a computer that records the data.

Nuclear quadrupole resonance (NQR) is similar to NMR in concept, but unlike NMR it does not rely on the nuclei aligning themselves in an externally applied magnetic field. Instead, NQR exploits the fact that some nuclei possess (for example ¹⁴N) an electric quadrupole moment, consequently, NQR transitions of nuclei can be detected in the absence of a magnetic field.

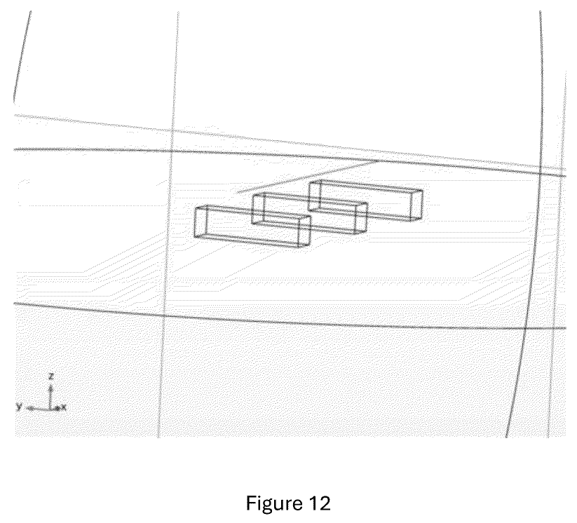

Trials have been conducted using a multi-sensor tine with three sets of magnets and two RF coils as shown in FIG. 12. The rectangular prism magnets are 50 mm×12.5 mm×12.5 mm and are 50 mm apart. The additional length is to ensure there is provided a pre-polarisation section which enables fast logging. Additional magnets Amy be provided. Where the number of magnets is N, the number of coils is N−1 and the number of measurements for a given location is N−1. The magnets were N50M NdFeB magnets available from kjmagnetics.

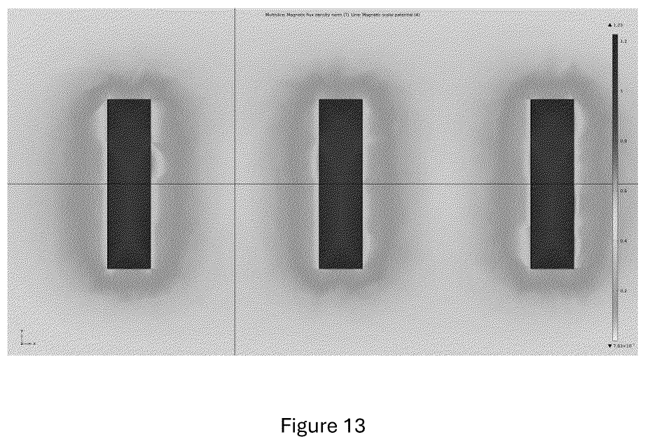

FIG. 13 depicts magnetic field potential lines (NormB) around the three magnets of FIG. 12. The magnets are polarised along the X-axis with the arrangement (−1, 1, −1).

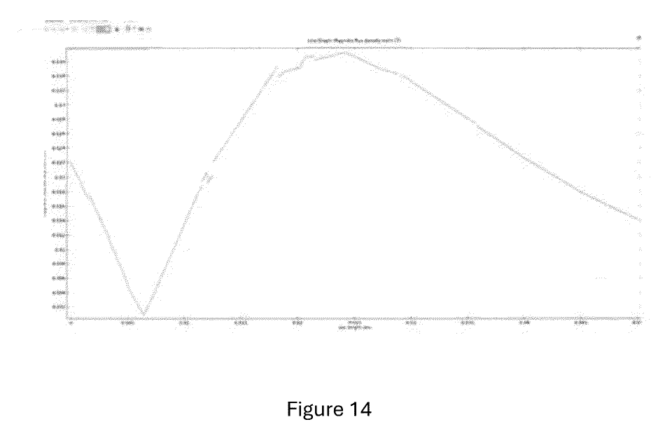

The static magnetic field B₀ is provided in FIG. 14. The NMR sensitive zones are at 0.05 m and 0.112 m. These are the 0 gradient points. FIG. 12 shows the B₀ field perpendicular to the magnet face. The 0 gradient at 0.023 m is the preferred spot for NMR measurement. A 0 gradient (DeltaB₀/DeltaZ) permits a large volume to be excited, ensuring that the magnet will not move out of the measurement zone during a pulse sequence.

In the absence of free water in a plot of land (i.e. in the absence of flooding), a short polarisation time of about 40 ms is needed. Subject to appropriate speeds, the soil engaging end of a magnet gets polarised before it reaches the RF coil at which point the pulse sequence is commenced as is known in the art. Approximately 10 kmhr¹ may be used by the vehicle to log the area of land.

The data is collected and correlated with GPS location information to create an elemental map of the plot of land. Where there are more than one NMR probe on the ground engaging element, the map may be three dimensional.

1. An apparatus for measuring soil moisture and composition, the apparatus comprising a ground engaging element adapted to break the surface of the soil, the ground engaging element comprising at least one NMR and/or NQR probe such that in use, the at least one NMR and/or NQR probe is under the surface of the soil.

2. An apparatus for measuring soil moisture and composition in accordance with claim 1 wherein the NMR and/or NQR probes are under the surface of the soil at substantially constant depths.

3. An apparatus for measuring soil moisture and composition in accordance with claim 1, wherein the apparatus comprises biasing means to maintain the ground engaging element at substantially constant depth during operation.

4. An apparatus for measuring soil moisture and composition in accordance with claim 1, wherein the apparatus is adapted to conduct constant NMR and/or NQR analyses while traversing an area of land.

5. An apparatus for measuring soil moisture and composition in accordance with claim 1, wherein the at least one NMR and/or NQR probes are provided on the ground engaging element such that they are maintained at substantially constant depth in the soil when in use.

6. An apparatus for measuring soil moisture and composition in accordance with claim 1, wherein the ground engaging element is provided in the form of a furrow former, a coulter or a knife.

7. An apparatus for measuring soil moisture and composition in accordance with claim 6, wherein the furrow former is provided in the form of a single disc or double discs or a knife point plough.

8. An apparatus for measuring soil moisture and composition in accordance with claim 6, wherein the furrow former is provided as a pair of rotatable discs adapted to engage the soil and form a furrow and a non-rotatable wheel is provided on one of the rotatable discs and wherein the plurality of NMR and/or NQR probes are provided on the non-rotatable wheel.

9. An apparatus for measuring soil moisture and composition in accordance with claim 1, wherein the apparatus further comprises at least one of a seed delivery system, a fertiliser delivery system and a water delivery system.

10. A method of measuring soil moisture and composition, wherein the method comprises conducting NMR and/or NQR analyses of soil below the surface at a substantially constant depth.

11. A method of measuring soil moisture and composition in accordance with claim 10, wherein the method comprises conducting NMR and/or NQR analyses of soil at multiple soil depths.

12. A method of measuring soil moisture and composition in accordance with claim 10, wherein the method comprises conducting NMR and/or NQR analyses of soil at multiple geospatial locations.

13. A method of measuring soil moisture and composition in accordance with claim 10, wherein the method comprises engaging the soil with a ground engaging element comprising at least one NMR and/or NQR probes and maintaining each NMR and/or NQR probe at a substantially constant depth while conducting NMR and/or NQR analyses.

14. A method of measuring soil moisture and composition in accordance with claim 13, wherein the method comprises, moving the ground engaging element comprising at least one NMR and/or NQR probes across the soil while conducting NMR and/or NQR analyses.

15. A method of measuring soil moisture and composition in accordance with claim 10, wherein the method comprises the additional step of conducting elemental analysis of the soil in real time and adjusting a planting, fertiliser and/or watering program.
